(19) United States
(12) Patent Application Publication
(10) Pub. No.: US 2010/0119819 A1
(43) Pub. Date: May 13, 2010

(54) COATING

(76) Inventors: John R. Rodgers, Ottawa (CA); Qi Yang, Ottawa (CA); Linruo Zhao, Ottawa (CA)

Correspondence Address: PATTERSON & SHERIDAN L.L.P. NJ Office, 3040 Post Oak Boulevard, Suite 1500, Houston, TX, 77056-6582, US

(21) Appl. No.: 12/593,898

(22) PCT Filed: Mar. 31, 2008
(86) PCT No.: PCT/CA2008/000598

§ 371 Date: Sep. 29, 2009

Related U.S. Application Data
(60) Provisional application No. 60/909,066, filed on Mar. 30, 2007.

(51) Int. Cl. B32B 18/00; C23C 30/00; C23C 14/16

(52) U.S. Cl. 428/334; 428/332

(57) ABSTRACT

A nanolayered coating, having a thickness of less than 100 nm, comprising nanolayers of: (i) TiN; and (ii) CrN, MoN, AlN, or AlN and CrN. The coating has an erosion rate, according to ASTM G76, at a particle velocity of 60 m/s and an impingement angle of 90°, of no greater than 4.0×10⁻³ mm³/g. Also provided is a monolithic TiAlN coating. Such coatings may be useful for erosion protection of aircraft or gas turbine components; or wear protection of gears, cutting tools including machine cutting tools and surgical cutting tools, or other metallic surfaces.

### FIELD OF THE INVENTION

The present invention relates generally to coatings. More particularly, the present invention relates to nanostructured coatings.

### BACKGROUND OF THE INVENTION

Coatings are used in various industries and have various purposes including extending the life of an article and enhancing the performance of an article.

For instance, coating technology is widely applied in the aerospace industry. By offering surface protection against environmental degradation, coatings can extend the life of aircraft or gas turbine structures, and enhance the performance of components. Coatings for aerospace applications can be deposited by a variety of techniques, including electroplating, thermal spray, chemical vapor deposition (CVD), physical vapor deposition (PVD), and the like.

Nanostructured hard coatings deposited by PVD have been under research and development worldwide for approximately the last 15 years. Many of the activities were focused on experimental process development to synthesize nanolayered (or superlattice) and nanocomposite thin-film coatings with super-high hardness. The process-structure-property-performance (PSPP) relationships were identified for a large number of coating systems. Although certain nanostructured wear-resistant coatings have been used to protect cutting tools for high-speed machining, their implementation in aerospace materials has remained a technological challenge. Further, existing nanostructured wear-resistant coatings used to protect cutting tools for high-speed machining have certain disadvantages.

It is, therefore, desirable to provide an improved coating or related application, process or use.

### SUMMARY OF THE INVENTION

It is an object of the present invention to obviate or mitigate at least one disadvantage of previous coatings, associated applications, processes, or uses.

In one aspect, the present invention provides a nanolayered coating, having a thickness of less than 100 nm, comprising nanolayers of (i) TiN; and (ii) CrN, MoN, AlN, or AlN and CrN; wherein the coating has an erosion rate, according to ASTM G76, at a particle velocity of 60 m/s and an impingement angle of 90°, of no greater than 4.0×10⁻³ mm³/g.

In one aspect, the present invention provides a nanolayered coating comprising nanolayers of TiN and CrN. In certain embodiments, the coating may have molar amounts of about 0.31 to 0.51 Ti, 0.07 to 0.20 Cr, 0.33 to 0.53 N, or about 0.41 Ti, 0.16 Cr, 0.43 N. In certain embodiments, the coating may have a wear rate of no greater than 1.4×10⁻⁶ mm³/N*m at a hardness of 27 to 36 GPa and a load of from 2N to 10N according to ASTM G99. In certain embodiments, the coating may have a coefficient of friction no greater than 0.95, or from 0.75 to 0.95, at a load of from 2N to 10N according to ASTM G 171-03. In certain embodiments, the coating may have an erosion rate, according to ASTM G76, at a particle velocity of 60 m/s and an impingement angle of 30°, of no greater than 1.0×10⁻³ mm³/g. In certain embodiments, the coating may have an erosion rate, according to ASTM G76, at a particle velocity of 60 m/s and an impingement angle of 90°, of no greater than 4.0×10⁻³ mm³/g, or no greater than 3.0×10⁻³ mm³/g.

In another aspect, the present invention provides a nanolayered coating comprising nanolayers of TiN and MoN. In certain embodiments, the coating may have an X_{Mo} of greater than 0.01, or from 0.3 to 0.6, where X_{Mo} is the molar ratio of Mo to Ti. In certain embodiments, the coating may have molar amounts of about 0.23 to 0.45 Ti, 0.19 to 0.36 Mo, 0.29 to 0.50 N, or about 0.26 to 0.40 Ti, 0.18 to 0.34 Mo, 0.39 to 0.42 N, or about 0.31 to 0.36Ti, 0.25 to 0.29 Mo, 0.39 to 0.40 N, or about 0.36 Ti, 0.25 Mo, 0.39 N, or about 0.31 Ti, 0.29 Mo, 0.40 N. In certain embodiments, the coating may have a wear rate of no greater than 1.0×10⁻⁶ mm³/N*m. In certain embodiments, the coating may have a hardness of at least 31.0 GPa according to ASTM E92-82 (using ASTM E384-99 as the indentation machine parameters and ASTM E3-01 as the guide for the preparation of the specimens). In certain embodiments, the coating may have a coefficient of friction no greater than 1.0, or no greater than 0.6, or from 0.4 to 0.6, according to ASTM G171-03. In certain embodiments, the coating may have an erosion rate, according to ASTM G76, at a particle velocity of 60 m/s and an impingement angle of 30°, of no greater than 1.1×10⁻³ mm³/g. In certain embodiments, the coating may have an erosion rate, according to ASTM G76, at a particle velocity of 60 m/s and an impingement angle of 90°, of no greater than 4.0×10⁻³ mm³/g, or of no greater than 2.0×10⁻³ mm³/g.

In another aspect, the present invention provides a nanolayered coating comprising nanolayers of TiN and AlN. In certain embodiments, the coating may have molar amounts of about 0.18 to 0.44 Ti, 0.18 to 0.51 Al, 0.27 to 0.51 N, or about 0.23 to 0.51 Ti, 0.053 to 0.41 Al, 0.36 to 0.44N, or about 0.23 to 0.35 Ti, 0.24 to 0.41 Al, 0.36 to 0.41N; or about 0.35 Ti, 0.24 Al, 0.41N; or about 0.29 Ti, 0.32 Al, 0.39 N; or about 0.23 Ti, 0.41Al, 0.36 N. In certain embodiments, the coating may have an erosion rate, according to ASTM G76, at a particle velocity of 60 m/s and an impingement angle of 90°, of no greater than 4.0×10⁻³ mm³/g, or of no greater than 1.0×10⁻³ mm³/g.

In another aspect, the present invention provides a nanolayered coating comprising nanolayers of TiN, AlN, and CrN. In certain embodiments, the coating may have molar amounts of about 0.21 to 0.39 Ti, 0.075 to 0.28 Al, 0.04 to 0.29 Cr, 0.29 to 0.52 N, or about 0.28 to 0.30 Ti; 0.10 to 0.22 Al, 0.06 to 0.23 Cr, 0.39 to 0.42 N; or about 0.30 Ti, 0.22 Al, 0.06 Cr, 0.42 N or about 0.28 Ti, 0.10 Al, 0.23 Cr, 0.39 N. In certain embodiments, the coating may have an erosion rate, according to ASTM G76, at a particle velocity of 60 m/s and an impingement angle of 30°, of no greater than 1.2×10⁻³ mm³/g. In certain embodiments, the coating may have an erosion rate, according to ASTM G76, at a particle velocity of 60 m/s and an impingement angle of 90°, of no greater than 4.0×10⁻³ mm³/g, or of no greater than 2.0×10⁻³ mm³/g.

In certain embodiments, the bilayer period of any of the nanolayered coatings may be, for instance, of less than 100 nm, from 0.1 nm to 50 nm, or from 6 to 18 nm.

In certain embodiments, the nanolayered coating, as described herein, may have an (200) orientation, and a bilayer period of from 6 to 18 nm, or from 7 to 17 nm, or from 8 to 14 nm, or from 9 to 11 nm, or about 10 nm.

In certain embodiments, the nanolayered coating, as described, herein may be randomly oriented, and have a bilayer period from 8 to 16 nm, or from 7 to 15 nm, or from 8 to 13 nm, or from 9 to 11 nm, or about 10 nm.

In another aspect, the present invention provides a process for coating an article comprising the steps of: applying a coating as described herein using an unbalanced magnetron sputtering system (UMS), a cathodic arc system, or an EB-PVD (Electron Beam Physical Vapor Deposition) system. In UMS, a bond coat of Ti may be used. For cathodic arc, a bond coat is not necessary.

In another aspect, the present invention provides a use of a coating, as described, herein for erosion protection of aircraft or gas turbine components; or wear protection of gears, machine cutting tools, surgical cutting tools, or other metallic surfaces. Metallic surface comprise, but are not limited to, stainless steel, tool steel, titanium alloys, titanium, and Ti-6Al-4V.

The substrate may be cleaned by chemical surface cleaning or plasma cleaning prior to coating.

Wear coatings, as described herein, may be used in aerospace applications, for instance, in gears, bearings, or seals.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 is a schematic of an unbalanced magnetron sputtering system (UMS) that may be used in applying coatings of embodiments of the invention;

FIG. 2 is a SEM (Scanning Electron Microscope) X-ray mapping image of a TiN/CrN (molar amounts of 0.25 Ti, 0.25 Cr, 0.50 N) nanolayered coating of an embodiment of the invention produced by the UMS process. The white layers are CrN, and the gray layers are TiN;

FIG. 3 is a graph showing hardness of TiN/CrN (molar amounts of 0.25 Ti, 0.25 Cr, 0.50 N) nanolayered coatings, of an embodiment of the invention, as a function of a bilayer period and orientation;

FIG. 4 is a graph showing coefficients of friction of TiN/CrN (molar amounts of 0.25 Ti, 0.25 Cr, 0.50 N) nanolayered coatings of an embodiment of the invention having a bilayer period of about 10 nm, and a conventional monolithic TiN coating as a function of hardness;

FIG. 5 is a graph showing wear rates of TiN/CrN (molar amounts of 0.25 Ti, 0.25 Cr, 0.50 N) nanolayered coatings of an embodiment of the invention and a conventional monolithic TiN coating as a function of hardness;

FIG. 6 is a graph showing coefficients of friction of TiN/MoN nanolayered coatings of an embodiment of the invention as a function of Mo concentration. When X_{Mo}=0, the data represents a conventional monolithic TiN coating;

FIG. 7 is a graph showing wear rates of TiN/CrN nanolayered coatings of an embodiment of the invention as a function of Mo concentration. When X_{Mo}=0, the data represents a conventional monolithic TiN coating;

FIG. 8 is a graph showing XPS (X-Ray Photoelectron Spectroscopy) Mo3d spectra taken from the wear track area of a coating surface;

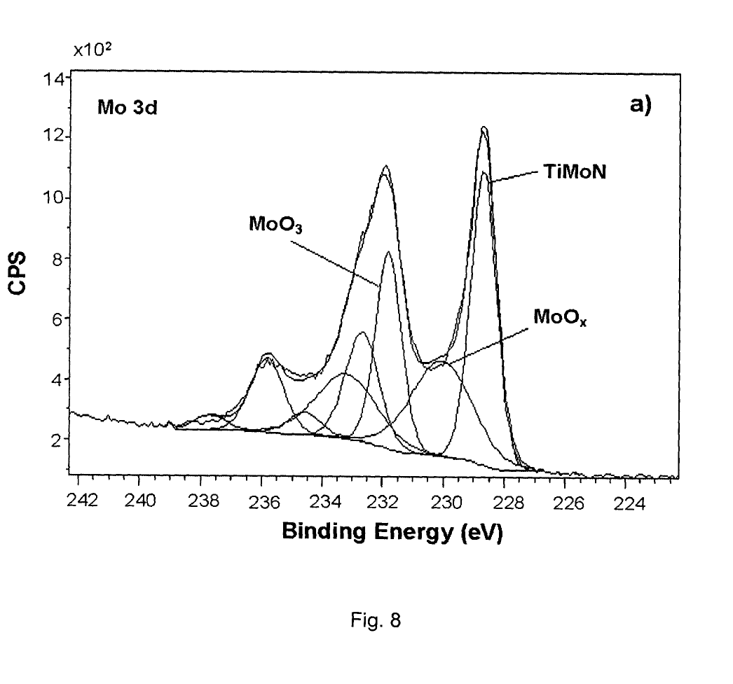

FIG. 9 is a graph showing erosion rates of TiN/AlN nanolayered coatings of an embodiment of the invention. The data for a conventional monolithic TiN coating are also listed as a baseline for comparison;

FIG. 10 is a graph showing erosion rates of TiN/CrN nanolayered coatings of an embodiment of the invention. The data for a conventional monolithic TiN coating are also listed as a baseline for comparison;

FIG. 11 is a graph showing erosion rates of TiN/MoN nanolayered coatings of an embodiment of the invention. The data for a conventional monolithic TiN coating are also listed as a baseline for comparison;

FIG. 12 is a graph showing erosion rates of TiN/AlN/CrN nanolayered coatings of an embodiment of the invention. The data for a conventional monolithic TiN coating are also listed as a baseline for comparison; and

FIGS. 13(a) and (b) are photographs of (a) an uncoated compressor blade, and (b) a TiN/AlN coated compressor blade of an embodiment of the invention.

### DETAILED DESCRIPTION

Generally, the present invention provides a nanostructured coating and related process and use. The coating has alternating nanolayers of a first metal nitride and a second metal nitride and, optionally, a third metal nitride. The coating may be used, for instance, in the aerospace industry.

### DEFINITIONS

A “nanostructured coating”, as used herein, means a coating having at least one dimension, namely the thickness, of less than 100 nm.

A “nanolayered coating” or “superlattice coating”, as used herein, mean a coating with repeating layers of at least two substances, wherein the bilayer or multilayer thickness is less than 100 nm.

A “bilayer thickness”, as used herein, means the thickness of one layer of a first substance plus the thickness of a second layer in a nanolayered or superlattice coating.

A “multilayer thickness”, as used herein, means the combined thickness of all non-repeating layers in a nanolayered or superlattice coating.

A “nanolayer”, as used herein, means a layer of one substance in a nanolayered or superlattice coating.

Experimental Techniques

The values and ranges provided correspond to exemplified embodiments and are not intended to strictly limit the scope of the invention.

Coating Deposition

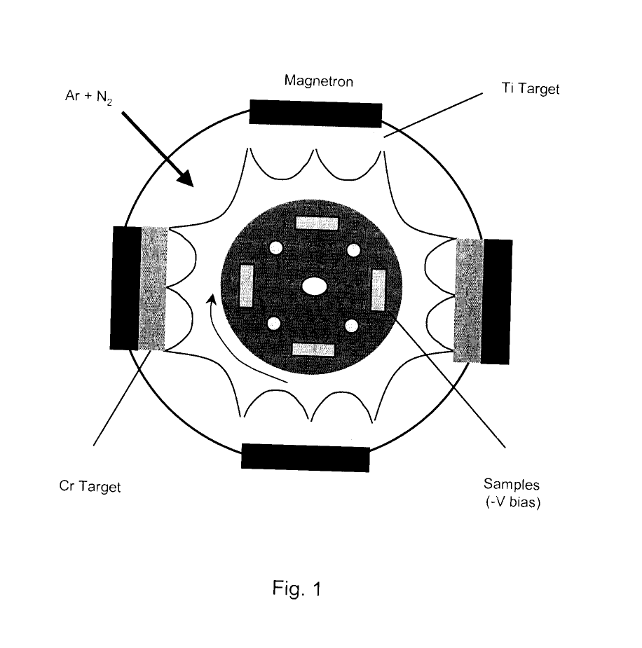

Nanostructured metal nitride coatings with designed compositions and microstructures were synthesized and deposited on titanium alloy Ti-6Al-4V (Ti, 6 wt % Al, 9 wt. % V) substrate specimens using a reactive unbalanced magnetron sputtering (UMS) technique. The substrate specimens used were flat discs of 2 inches in diameter and ⅛ inch in thickness. Ti-6Al-4V is an alloy used, for instance, for engine compressor blades. FIG. 1 is a schematic of a UMS technique deposition chamber where metal nitride coatings were synthesized from elemental metal targets and N₂ gas. Ar gas was used in the process to generate plasma. To deposit coatings with consistent quality and controlled composition and microstructure, systematic parametric studies were carried out to define the processing windows. The main processing parameters include target current, Ar flow rate, substrate bias and N₂ supply control as discussed further below.

The surface of the substrate specimens was mechanically polished down to 1 μm diamond paste, followed by cleaning in detergent and ultrasonic cleaning in Vasol™ and alcohol solutions.

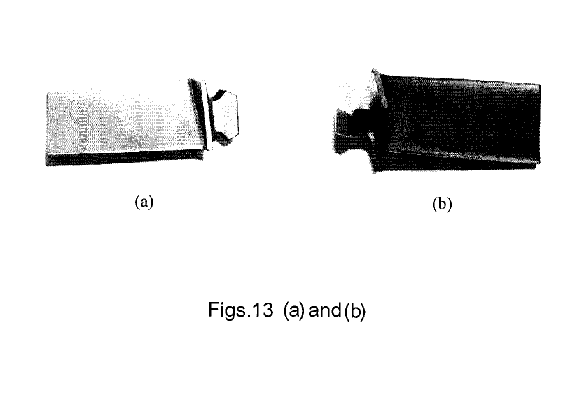

The laboratory flat disc specimens were mounted on flat disc back-plates with a larger diameter. The specimen/back-plate assembly was then mounted near the edge of a round specimen holder that rotates along its central axis with the specimens facing the targets (see FIG. 1). Compressor blades were mounted on secondary part holders, which were then mounted near the edge of the primary holder. When the primary holder rotates, the secondary holders also rotate through a mechanical gear device to achieve 3-dimensional deposition. FIGS. 13(a) and (b) are photographs of (a) an uncoated compressor blade and (b) a TiN/AlN coated compressor blade.

TiAIN, TiCrN, TiMoN and TiAlCrN coatings were synthesized and deposited on the substrates in the UMS system from pure Ti, Al, Cr and Mo elemental metal targets. The purities of the targets were 99.9 wt. %.

The target currents applied to produce the specified coatings are listed in the following tables 1 to 4.

TABLE 1
Target currents applied for TiAlN coatings

| Ti Target | Al Target | Composition |
|---|---|---|
| Current (A) | Current (A) | (molar amounts) |
| 8.0 | 3 | 0.35Ti, 0.24Al, 0.41N |
| 8.0 | 4.4 | 0.29Ti, 0.32Al, 0.39N |
| 8.0 | 5.5 | 0.23Ti, 0.41Al, 0.36N |

2 Ti targets and 2 Al targets were used.

TABLE 2
Target currents applied for TiCrN coating

| Ti Target | Al Target | Composition |
|---|---|---|
| Current (A) | Current (A) | (molar amounts) |
| 8.0 | 2 | 0.41Ti, 0.16Cr, 0.43N |

2 Ti targets and 1 Cr target were used.

TABLE 3
Target currents applied for TiMoN coatings

| Ti Target | Al Target | Composition |
|---|---|---|
| Current (A) | Current (A) | (molar amounts) |
| 8.0 | 2.1 | 0.36Ti, 0.25Mo, 0.39N |
| 8.0 | 2.5 | 0.31Ti, 0.29Mo, 0.40N |

2 Ti targets and 2 Mo targets were used.

TABLE 4
Target current applied for TiAlCrN coatings

| Ti Target | Al Target | Cr Target | Composition |
|---|---|---|---|
| Current (A) | Current (A) | Current (A) | (molar amounts) |
| 8.0 | 5.5 | 1.5 | 0.30Ti, 0.22Al, 0.06Cr, 0.42N |
| 8.0 | 3.0 | 3.0 | 0.28Ti, 0.10Al, 0.23Cr, 0.39N |

2 Ti targets, 1 Al and Cr target were used.

The argon flow rate used in the deposition processes to produce the specified coatings was 10 sccm (sccm=standard cubic centimeter per minute). The substrate bias used in the deposition processes to produce the specified coatings was −50V. The OEM (Original Equipment Manufacturer) value used in the deposition processes to produce the specified coatings was 40 to 50% depending on the specific target current arrangement. The deposition temperature in the processes was below 250° C. and in the range of 180 to 220° C. No radiation heating was applied in the processes. The deposition time used in the deposition processes to produce the specified coatings was 2.5 to 5.5 hours, depending on the specific target current setting in order to deposit coatings of 6 μm (target) in thickness.

The coating thickness was in the range of 5.5 to 6.5 μm. The specified TiAlN, TiCrN, TiMoN and TiAlCrN coatings had columnar grains and nanolayered structures. The growth direction of the columnar grains was perpendicular to the substrate surface. The nanolayered structures were formed as a result of using substantially pure elemental targets in the deposition. The layers consist of alternating binary nitrides. Specifically, they are: TiN/AlN/TiN/AlN/ . . . for TiAl coating, TiN/CrN/TiN/CrN/ . . . for TiCrN coating, TiN/MoN/TiN/MoN/ . . . for TiMoN coating, and TiN/AlN/CrN/TiN/AlN/CrN/ . . . for TiAlCrN coating.

Coating Characterization

The composition and grain morphology and size of the coatings were analyzed by scanning electron microscopy (SEM) and energy dispersive spectroscopy (EDS). X-ray diffraction (XRD) technique was used to identify the crystalline structure and preferred orientation of the phase constituents, whilst small-angle X-ray reflectivity measurement was employed to determine the bi/multi-layer period of nanolayered coatings. For mechanical properties, nanoindentation and scratch testing techniques were used to measure coating hardness and adhesion strength. The wear- and erosion-resistant properties were assessed by a pin-on-disc dry-sliding test and a solid-particle erosion test. The erosion test was performed according to ASTM-G76. The wear test was performed according to ASTM-G99.

Coating Deposition and Characterization

Nanostructured Wear-Resistant Coatings

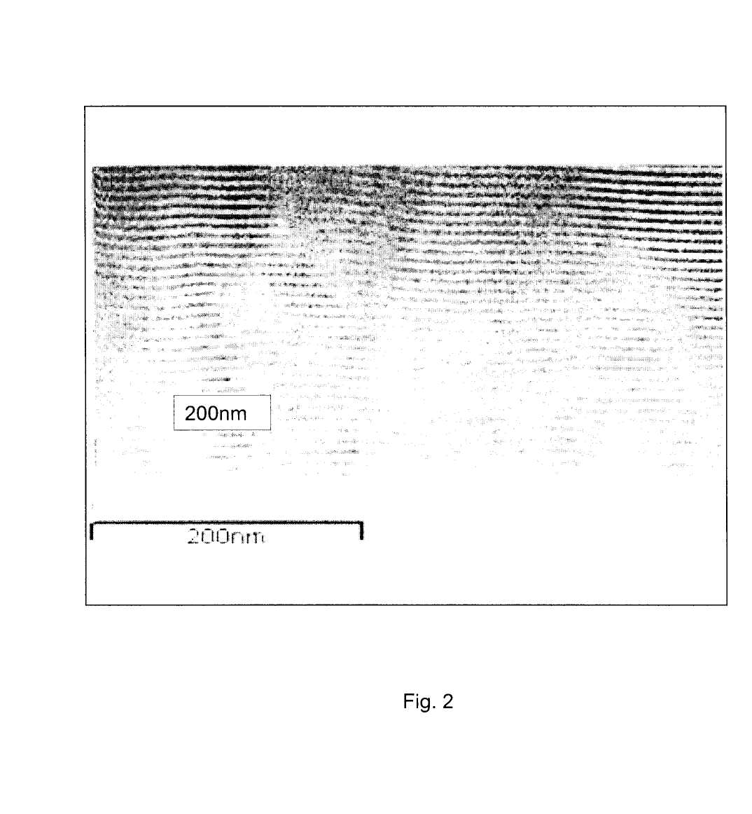

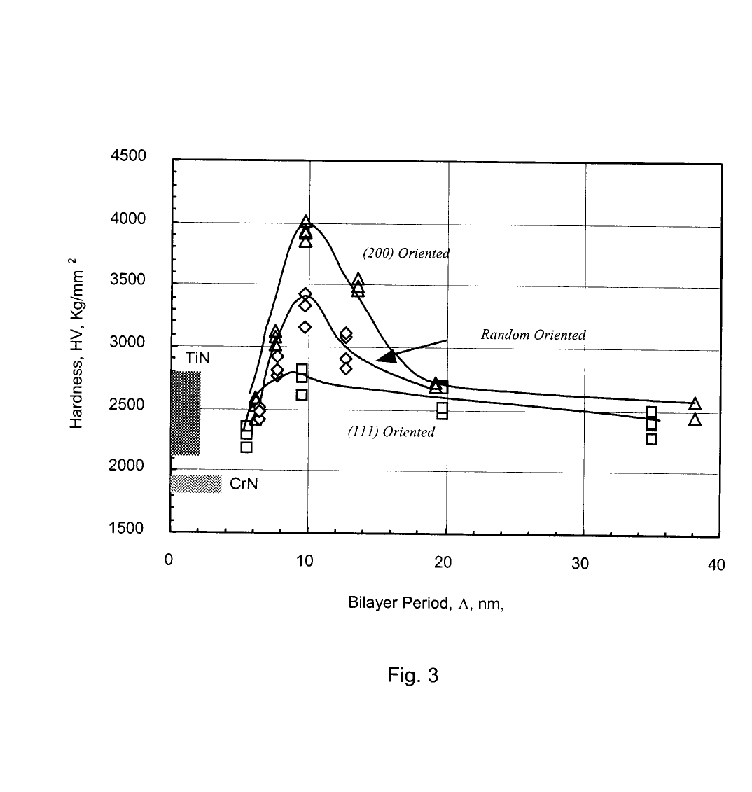

Two coating properties are considered important to affect wear resistance: hardness and coefficient of friction. In general, coatings with higher hardness and smaller coefficients of friction have better wear resistance. FIG. 2 is a SEM X-ray mapping image of a TiN/CrN nanolayered coating produced by the UMS process. The white layers are CrN, and the gray layers are TiN. In the experiments, the rotation pattern of the specimen holder was controlled in such a way that coatings with different bilayer periods (Λ=TiN layer thickness+CrN layer thickness) were produced for hardness testing. FIG. 3 presents hardness of TiN/CrN nanolayered coatings as a function of a bilayer period and preferred orientation. TiN/CrN coating with Λ≈10 nm and (200) preferred orientation yields hardness values (˜40 GPa) almost twice higher than those for monolithic TiN and CrN coatings. This hardness enhancement is much larger than that predicted by the “rule of mixtures”, and is achieved by a combination of proper selection of constituent materials, e.g. TiN and CrN, and effective dislocation-interface interactions in the nanolayered structure.

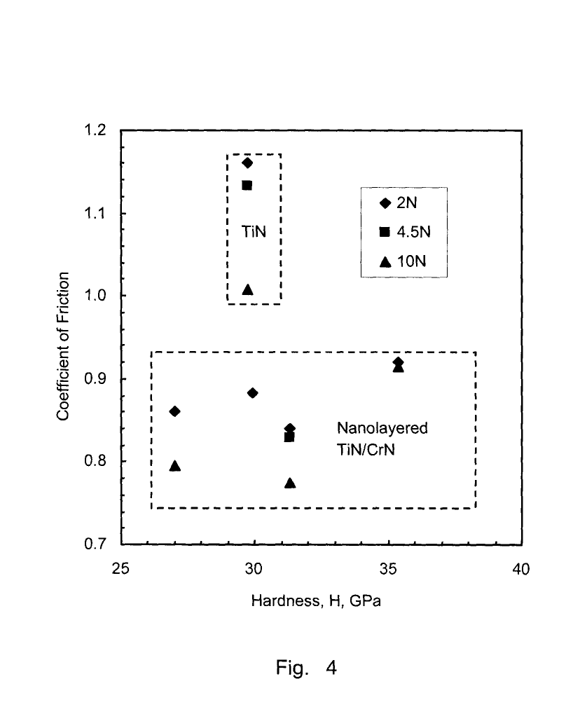

The coefficient of friction of TiN/CrN nanolayered coatings is compared with those for a monolithic TiN coating in FIG. 4. The data were generated from pin-on-disc dry-sliding tests against a WC-Co pin under three loading conditions. Dry sliding wear tests were conducted at 22±2° C. and 20±1% RH (Relative Humidity) using a pin-on-disc wear tester. A 5 mm diameter WC-6% Co ball was employed as the pin counterpart, and the coated specimens were tested as the disc. The tests were carried out at three different applied loads (2, 4.5 and 10N) and a sliding speed of 20 cm/s, with frictional force recorded continuously. The average coating wear volumes, from which the specific wear rates were determined by normalizing them with the sliding distance and applied load, were calculated based on the wear track diameter and the wear depth profiles at several locations.

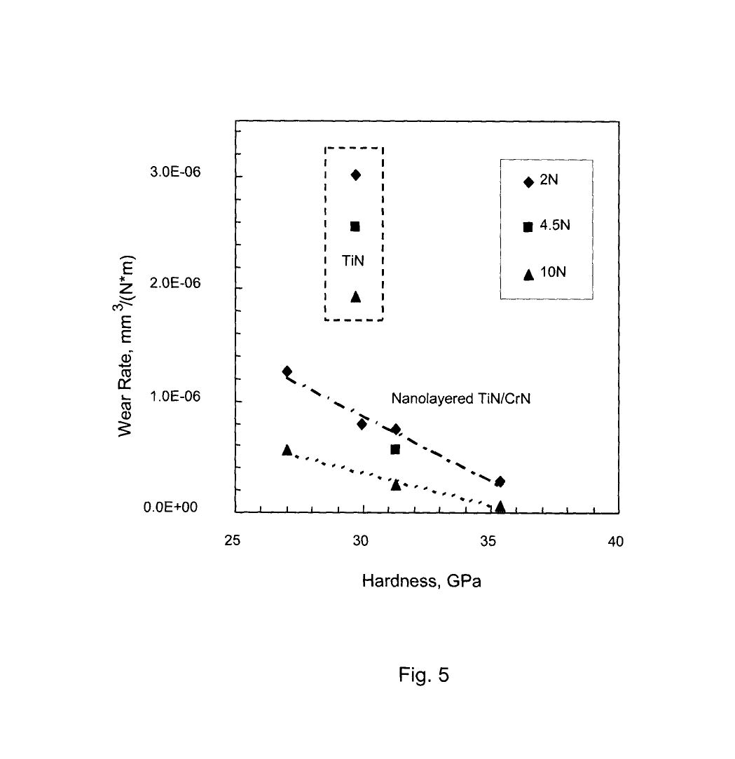

For the former coatings, their coefficients of friction are in the range of 0.75 to 0.95, or about 10 to 30% smaller than those for the latter coating. Combining the reduced coefficients of friction with markedly enhanced hardness, TiN/CrN nanolayered coatings exhibited wear rates about 3 to 20 times lower than those for monolithic TiN coating in pin-on-disc tests. The results of the tests are illustrated in FIG. 5, where the wear rates of TiN/CrN nanolayered coatings normalized by applied load are shown to decrease with hardness.

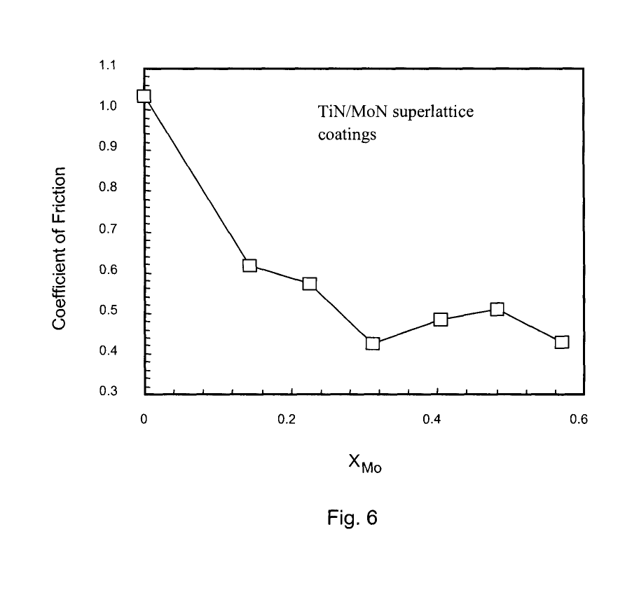

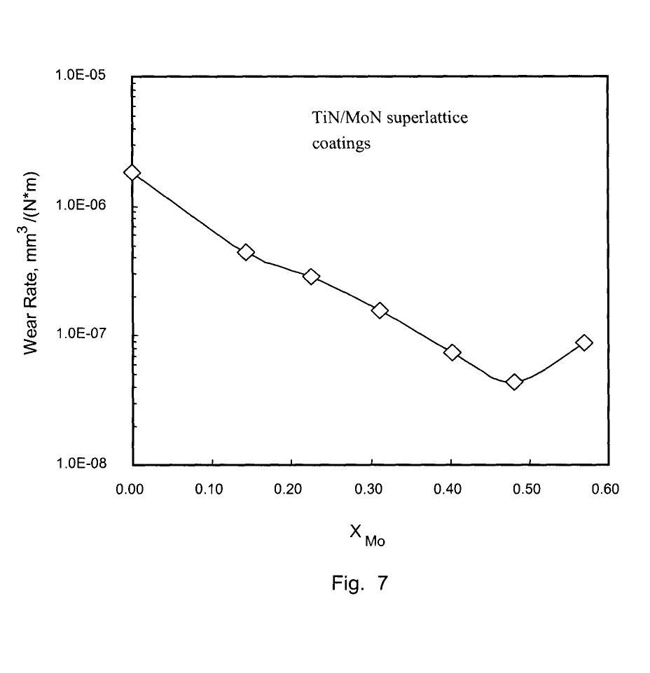

TiN/MoN nanolayered coatings are also very effective in improving wear resistance, and the improvement was found to primarily result from dramatic reduction in coefficients of friction. As shown in FIG. 6, the coefficients of friction for TiN/MoN nanolayered coatings decrease with Mo concentration (X_{Mo}), reaching the lowest values of 0.4-0.5 at X_{Mo}=0.3-0.6. Note that these values are one-half of that for TiN coating. When X_{Mo}=0, the data represents a monolithic TiN coating. Table 5 lists the hardness and Young's modulus of TiN/MoN nanolayered coatings measured by nanoindentation. Although the hardness enhancement is fairly moderate in comparison with TiN/CrN nanolayered coatings, TiN/MoN nanolayered coatings can still yield wear rates of 20-40 times smaller than that for monolithic TiN coating, as shown FIG. 7, owing to the lowered coefficients of friction. When X_{MO}=0, the data represents a monolithic TiN coating. X-ray photoelectron spectroscopy (XPS) revealed that it is the MoO₃ formed on the wear track that provided “dry lubrication” effect during pin-on-disc wear tests.

TABLE 5
Hardness and Young's modulus of TiN/MoN nanolayered
coatings at different Mo concentrations.

| X_{Mo} | H, GPa | E, GPa |
|---|---|---|
| 0.00 | 30.8 | 331 |
| 0.14 | 32.9 | 384 |
| 0.23 | 28.5 | 325 |
| 0.31 | 33.3 | 363 |
| 0.40 | 34.1 | 367 |
| 0.48 | 34.4 | 344 |
| 0.57 | 31.2 | 332 |

Erosion protection of gas turbine compressor components represents an important application for nanostructured hard coatings. Achieving superior erosion resistance requires coatings having high hardness and good toughness because of the impact-fatigue loading by high velocity solid particles. Four nanolayered coatings, namely TiN/AlN, TiN/CrN, TiN/MoN and TiN/AlN/CrN, were synthesized and deposited on Ti-6Al-4V substrate using the reactive UMS technique. These coatings contain TiN as the main constituent, and the concentrations of the second and third elements, i.e. Al, Cr and Mo, were varied systematically in the experiments to investigate their effects on hardness and erosion resistance.

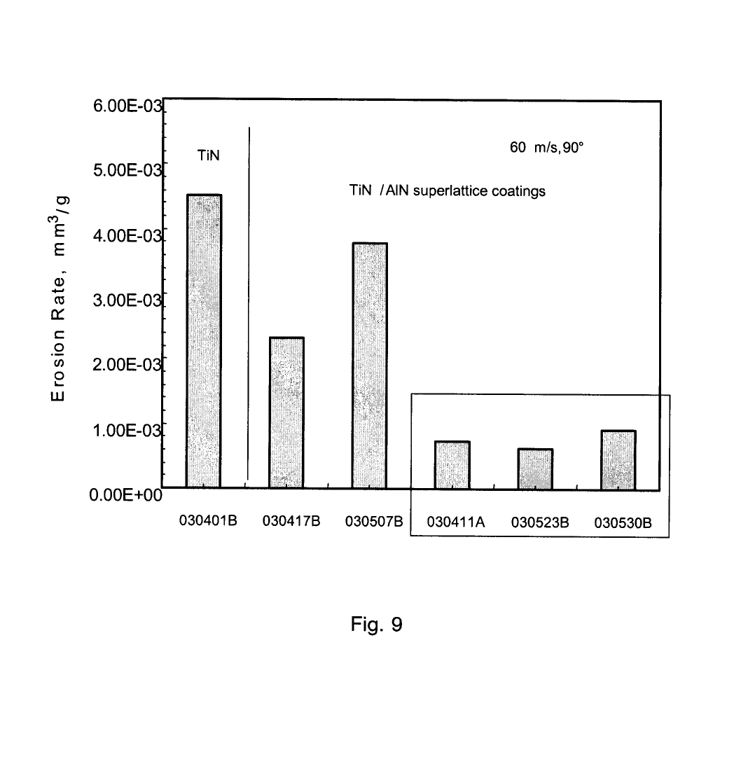

FIGS. 9 to 12 present erosion rates of TiN/AlN, TiN/CrN, TiN/MoN and TiN/AlN/CrN nanolayered coatings from solid-particle erosion tests following ASTM G76 standard. The tests were performed at a particle velocity of 60 m/s and three impingement angles of 30°, 60° and 90°. The erosion rates of monolithic TiN coating are also listed as a baseline for comparison. Table 6 indicates the composition of the samples.

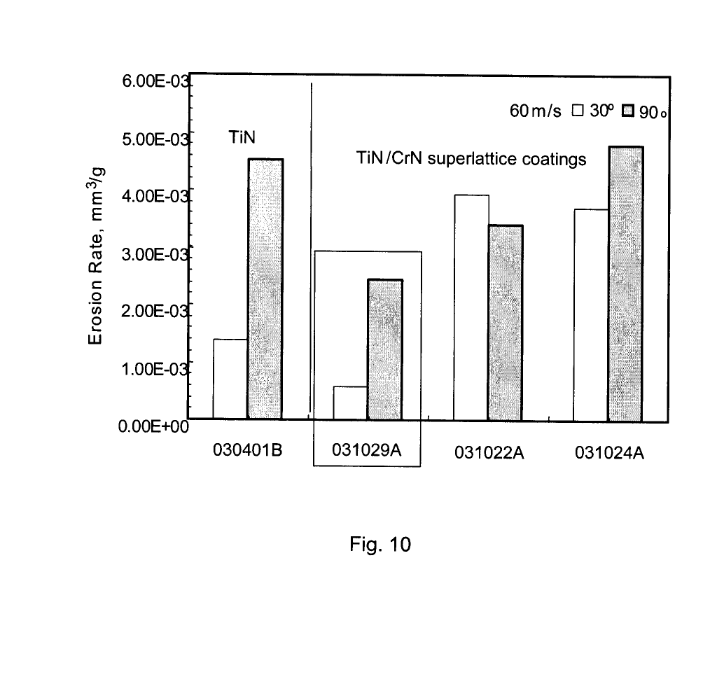

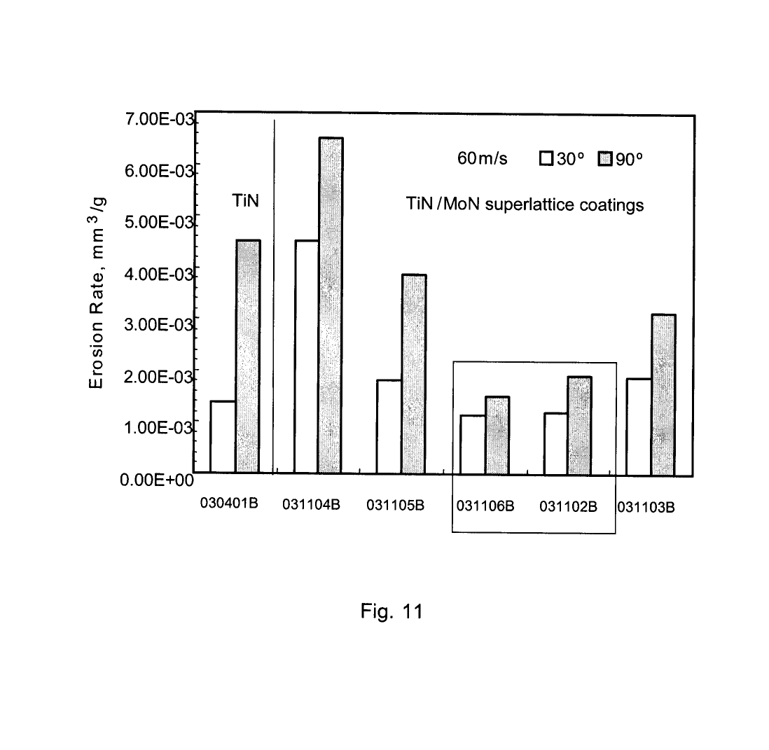

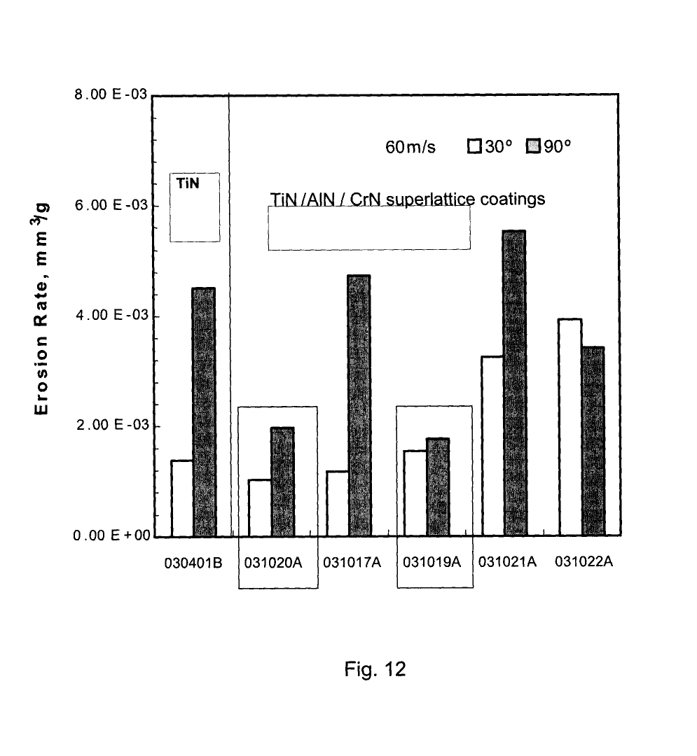

TABLE 6
Compositions of the samples of FIG. 9 to 12

| Sample ID | Composition (mol. %) |
|---|---|
| 030401B (FIGS. 9 to 12) | TiN |
| 030417B (FIG. 9) | 50.6 Ti, 5.3 Al, 44.1 N |
| 030507B (FIG. 9) | 40.9 Ti, 15.6 Al, 43.5 N |
| 030411A (FIG. 9) | 35 Ti, 24 Al, 41 N |
| 030523B (FIG. 9) | 29 Ti, 32 Al, 39 N |
| 030530B (FIG. 9) | 23 Ti, 41 Al, 36 N |
| 031029A (FIG. 10) | 41 Ti, 16 Cr, 43 N |
| 031022A (FIG. 10) | 32 Ti, 28.8 Cr, 39.2 N |
| 031024A (FIG. 10) | 24.3 Ti, 41.6 Cr, 34.1 N |
| 031104B (FIG. 11) | 44.5 Ti, 13.5 Mo, 42.5N |
| 031105B (FIG. 11) | 40.3 Ti, 18.2 Mo, 41.5 N |
| 031106B (FIG. 11) | 36 Ti, 25 Mo, 39 N |
| 031102B (FIG. 11) | 31 Ti, 29 Mo, 40 N |
| 031103B (FIG. 11) | 26.1 Ti, 34.5 Mo, 39.4 N |
| 031020A (FIG. 12) | 30 Ti, 22 Al, 6 Cr, 42N |
| 031017A (FIG. 12) | 30.7 Ti, 15.6 Al, 12.1 Cr, 41.6 N |
| 031019A (FIG. 12) | 28 Ti, 10 Al, 23 Cr, 39 N |
| 0301021A (FIG. 12) | 28.4 Ti, 2.6 Al, 31.3 Cr, 37.3N |
| 031022A (FIG. 12) | 32.0 Ti, 0 Al, 28.8 Cr, 39.2 N |

In the figures, the coatings with the greatest improvement in erosion resistance are highlighted (by way a box), and the specimen composition, hardness and erosion rate of these coatings are summarized in Tables 7 to 10. Even certain coatings not highlighted showed improved properties over the monolithic coating and represent embodiments of this invention. It is noteworthy that TiN/AlN nanolayered coatings with certain compositions demonstrate the best improvement in erosion resistance, with erosion rates only 1/7 of that for monolithic TiN coating. The other nanolayered coatings exhibit erosion rates of ½ to ⅓ of that for TiN coating. From these results generated on flat coupon specimens, UMS trials were conducted to deposit a TiN/AlN nanolayered coating on engine compressor blades, as shown in FIG. 13. Results highlighted indicate the greatest improvement in erosion resistance.

TABLE 7
Hardness, Young's Modulus, and erosion rates of the TiN/AlN nanolayered
coatings and of a conventional monolithic TiN coating.

| | Hardness | Young's | Erosion Rate (mm³/g) | | |
|---|---|---|---|---|---|
| Coating Composition | (GPa) | Modulus (GPa) | 30° | 60° | 90° |
| TiN | 30.8 | 331 | 1.38E−3 | 2.2E−3 | 4.5E−3 |
| 0.35Ti, 0.24Al, 0.41N | 33.6 | 371 | — | — | 7.2E−4 |
| 0.29Ti, 0.32Al, 0.39N | 36.0 | 381 | 4.23E−4 | 5.52E−4 | 6.0E−4 |
| 0.23T1, 0.41Al, 0.36N | 31.4 | 337 | — | — | 9.8E−4 |

TABLE 8
Hardness, Young's Modulus, and erosion rate of a TiN/CrN nanolayered
coating and of a conventional monolithic TiN coating.

| Coating | Hardness | Young's | Erosion Rate (mm³/g) | |
|---|---|---|---|---|
| Composition | (GPa) | Modulus (GPa) | 30° | 90° |
| TiN | 30.8 | 331 | 1.38E−3 | 4.5E−3 |
| 0.41Ti, 0.16Cr, | 36.3 | 362 | 5.67E−4 | 2.44E−3 |
| 0.43N | | | | |

TABLE 9
Hardness, Young's Modulus, and erosion rates of TiN/MoN nanolayered
coatings and of a conventional monolithic TiN coating.

| Coating | Hardness | Young's | Erosion Rate (mm³/g) | |
|---|---|---|---|---|
| Composition | (GPa) | Modulus (GPa) | 30° | 90° |
| TiN | 30.8 | 331 | 1.38E−3 | 4.5E−3 |
| 0.36Ti, 0.25Mo, | 34.1 | 367 | 1.14E−4 | 1.52E−3 |
| 0.39N | | | | |
| 0.31Ti, 0.29Mo, | 34.4 | 344 | 1.20E−3 | 1.90E−3 |
| 0.40N | | | | |

TABLE 10
Hardness, Young's Modulus, and erosion rates
of TiN/AlN/CrN nanolayered coatings and of
a conventional monolithic TiN coating.

| Coating | Hardness | Young's | Erosion Rate (mm³/g) | |
|---|---|---|---|---|
| Composition | (GPa) | Modulus (GPa) | 30° | 90° |
| TiN | 30.8 | 331 | 1.38E−3 | 4.5E−3 |
| 0.30Ti, 0.22Al, | 33.6 | 355 | 1.03E−4 | 1.97E−3 |
| 0.06Cr, 0.42N | | | | |
| 0.28Ti, 0.10Al, | 34.9 | 336 | 1.55E−3 | 1.76E−3 |
| 0.23Cr, 0.39N | | | | |

Wear Rate and Friction Coefficient

The wear rates and friction coefficients measured by pin-on-disc testing of selected coatings with better wear resistance than TiN coating are listed in Table 10. The wear rate and friction coefficient of TiN coating are included as the baseline reference. Testing conditions were as follows: sliding speed: 20 cm/s, sliding counterpart: WC-6% Co ball, RH %: 20% testing temperature: room temperature, load: 10N.

TABLE 10
Wear rate and Friction Coefficient of a TiN/MoN nanolayered
coating and a conventional monolithic TiN coating.

| | Wear Rate | Friction |
|---|---|---|
| Formulation (at. %) | (mm³/(N*m)) | Coefficient |
| TiN | 1.80E−6 | 1.03 |
| 0.36Ti, 0.25Mo, 0.39N | 5.69E−8 | 0.43 |
| 0.31Ti, 0.29Mo, 0.40N | 4.39E−8 | 0.51 |

In another experiment, monolithic layers of TiAlN were formed using Ti and Al powders in a nitrogen gas chamber and deposited using cathodic arc Physical Vapor Deposition (PVD). In this experiment, casting was used but HIPping (Hot Isostatic pressing) could also be used. The substrates were blades of Ti-6Al-4V and 17.4 PH stainless steel. The monolayer coating thickness ranged from 8.0 microns to 14.3 microns. In one embodiment, the thickness is less than 100 nm. The average molar amounts were Ti: 30.6, Al: 29.4; N: 40.0. It is expected that these molar ranges could be varied by at least 5%, 10%, or 20%. Erosion rates for these coatings are shown in Table 11. In certain embodiments, there is provided a monolithic TiAlN coating, having a thickness of less than 100 nm, wherein the coating has an erosion rate, according to ASTM G76, at a particle velocity of 84 m/s and an impingement angle of 90°, of no greater than 4.0×10⁻³ mm³/g, or no greater than 3.0×10⁻³ mm³/g, or no greater than 2.0×10⁻³ mm³/g, or no greater than 1.8×10⁻³ mm³/g.

TABLE 11
Erosion rate of a monolithic TiAlN coating

| | | Erosion Rate, mm³/g | | | Total Erodent Used, gram | | |
|---|---|---|---|---|---|---|---|
| | | Coated | | | Coated | | |
| | Uncoated | Run#12 | Run#13 | Average | Run#12 | Run#13 | Average |
| Stage-1 | 2.07E−02 | 1.39E−03 | 1.75E−03 | 1.57E−03 | 145 | 123 | 134 |
| Stage-2 | 2.32E−02 | 1.41E−03 | 1.78E−03 | 1.60E−03 | 117 | 97 | 107 |
| Average | 2.20E−02 | 1.40E−03 | 1.77E−03 | | 131 | 110 | |

| | |
|---|---|
| 1.58E−03 | 121 |

In the above tests, the following standards were used: Hardness: ASTM E92-82 (using ASTM E384-99 as the indentation machine parameters and ASTM E3-01 as the guide for the preparation of the specimens); erosion rate: ASTM G76; wear rate: ASTM G99; and coefficient of friction: ASTM G171-03.

In the preceding description, for purposes of explanation, numerous details are set forth in order to provide a thorough understanding of the embodiments of the invention. However, it will be apparent to one skilled in the art that these specific details are not required in order to practice the invention.

The above-described embodiments of the invention are intended to be examples only. Alterations, modifications and variations can be effected to the particular embodiments by those of skill in the art without departing from the scope of the invention.

1. A nanolayered coating, having a thickness of less than 100 nm, comprising nanolayers of:
(i) TiN; and
(ii) CrN, MoN, AlN, or AlN and CrN; wherein the coating has an erosion rate, according to ASTM G76, at a particle velocity of 60 m/s and an impingement angle of 90°, of no greater than 4.0×10⁻³ mm³Vg.

2. A nanolayered coating according to claim 1, wherein the coating comprises nanolayers of TiN and CrN in molar amounts of 0.31 to 0.51 Ti, 0.07 to 0.20 Cr, and 0.33 to 0.53 N.

3. A nanolayered coating according to claim 1, wherein the coating has a hardness of at least 31.0 GPa according to ASTM E92-82.

4. A nanolayered coating according to claim 1, wherein the coating has an erosion rate, according to ASTM G76, at a particle velocity of 60 m/s and an impingement angle of 30°, of no greater than 1.0×10⁻³ mm³Vg.

5. A nanolayered coating according to claim 1, wherein the coating has an erosion rate, according to ASTM G76, at a particle velocity of 60 m/s and an impingement angle of 90°, of no greater than 3.0×10⁻³ mm³Vg.

6. A nanolayered coating according to claim 1, having a wear rate of no greater than 1.4×10⁻⁶ mm³/N*m at a hardness of 27 to 36 GPa and a load of from 2N to ION, according to ASTM G99.

7. A nanolayered coating according to claim 1, wherein the coating has a coefficient of friction no greater than 0.95, at a load of from 2N to ION according to ASTM GI 71-03.

8. A nanolayered coating according to claim 1, wherein the coating has a coefficient of friction from 0.75 to 0.95, at a load of from 2N to ION according to ASTM G171-03.

9. A nanolayered coating according to claim 1, wherein the coating comprises nanolayers of TiN and MoN in molar amounts of 0.23 to 0.45 Ti, 0.19 to 0.36 Mo, and 0.29 to 0.50 N.

10. A nanolayered coating according to claim 9, having a wear rate of no greater than 1.0×10⁻⁶ mm³/N*m, according to ASTM G99.

11. A nanolayered coating according to claim 9, wherein the coating has a hardness of at least 31.0 GPa, at a load of from 2N to 10N according to ASTM E92-82.

12. A nanolayered coating according to claim 9, wherein the coating has a coefficient of friction no greater than 1.0, at a load of from 2N to ION according to ASTM G171-03.

13. A nanolayered coating according to claim 9, wherein the coating has a coefficient of friction no greater than 0.6, at a load of from 2N to ION according to ASTM G171-03.

14. A nanolayered coating according to claim 9, wherein the coating has a coefficient of friction from 0.4 to 0.6, at a load of from 2N to ION according to ASTM G171-03.

15. A nanolayered coating according to claim 9, wherein the coating has an erosion rate, according to ASTM G76, at a particle velocity of 60 m/s and an impingement angle of 30°, of no greater than 1.0×10⁻³ mm³Vg.

16. A nanolayered coating according to claim 9, wherein the coating has an erosion rate, according to ASTM G76, at a particle velocity of 60 m/s and an impingement angle of 90°, of no greater than 2.0×10⁻³ mm³Vg.

17. A nanolayered coating according to claim 1, wherein the coating comprises nanolayers of TiN and AlN in molar amounts of 0.18 to 0.44 Ti, 0.18 to 0.51 Al, and 0.27 to 0.51 N.

18. A nanolayered coating according to claim 17, wherein the coating has an erosion rate, according to ASTM G76, at a particle velocity of 60 m/s and an impingement angle of 90°, of no greater than 1.0×10⁻³ mm³Vg.

19. A nanolayered coating according to claim 1, wherein the coating comprises nanolayers of TiN, AlN, CrN in molar amounts of 0.21 to 0.39 Ti, 0.075 to 0.28 Al, and 0.04 to 0.29 Cr.

20. A nanolayered coating according to claim 19, wherein the coating has an erosion rate, according to ASTM G76, at a particle velocity of 60 m/s and an impingement angle of 30°, of no greater than 1.2×10⁻³ mm³Vg.

21. A nanolayered coating according to claim 19, wherein the coating has an erosion rate, according to ASTM G76, at a particle velocity of 60 m/s and an impingement angle of 90°, of no greater than 2.0×10⁻³ mm³Vg.

22. A nanolayered coating according to claim 1 having a multilayer thickness of from 0.1 nm to 50 nm.

23. A nanolayered coating according to claim 9 having a multilayer thickness of from 6 to 18 nm.

24. A nanolayered coating according to claim 1 having a (200) orientation, and a multilayer thickness of from 6 to 18 nm.

25. A nanolayered coating according to claim 1 having a (200) orientation, and a multilayer thickness of from 9 to 11 nm.

26. A nanolayered coating according to claim 1 being randomly oriented, and having a multilayer thickness from 8 to 16 nm.

27. A nanolayered coating according to claim 1 being randomly oriented, and having a multilayer thickness from 9 toll nm.

28. A monolithic TiAlN coating, having a thickness of less than 100 nm, wherein the coating has an erosion rate, according to ASTM G76, at a particle velocity of 84 m/s and an impingement angle of 90°, of no greater than 4.0×10⁻³ mm³Vg.

29. An aircraft or gas turbine component, a gear, a bearing, a seal, a machine cutting tool, or a surgical cutting tool coated with the nanolayer coating of claim 1.

30. A coating according to claim 1 coating stainless steel, tool steel, a titanium alloy, titanium, or Ti-6Al-4V.

31. An aircraft or gas turbine component, a gear, a bearing, a seal, a machine cutting tool, or a surgical cutting tool coated with the nanolayer coating of claim 1, wherein the coating is applied by an unbalanced magnetron sputtering system.
